(19) United States
(12) Patent Application Publication
(10) Pub. No.: US 2026/0052942 A1
(43) Pub. Date: Feb. 19, 2026

(54) SEMICONDUCTOR DEVICE MANUFACTURING EQUIPMENT

(71) Applicant: SAMSUNG ELECTRONICS CO., LTD., Suwon-si (KR)

(72) Inventors: Jun Sang Kim, Suwon-si (KR); Hyeon Jun Yun, Suwon-si (KR); Yun Ha Kim, Suwon-si (KR); Sang Ha Park, Suwon-si (KR); Kyoung Whan Oh, Suwon-si (KR); Hung Suk You, Suwon-si (KR); Joong-Ha Lee, Suwon-si (KR); Gee Woong Jung, Suwon-si (KR); Han Sung Cho, Suwon-si (KR)

(21) Appl. No.: 19/018,900

(22) Filed: Jan. 13, 2025

(30) Foreign Application Priority Data
Aug. 19, 2024 (KR) 10-2024-0110678

(51) Int. Cl. H01L 21/68; G05B 19/404; H01L 21/67

(52) U.S. Cl. CPC H01L 21/68; G05B 19/404; H01L 21/67144; G05B 2219/34083

(57) ABSTRACT

The present disclosure relates to semiconductor-device manufacturing equipment. An example semiconductor-device manufacturing equipment incudes a stage that supports a substrate, a head module disposed on top of the stage and including a first bonding head and a second bonding head spaced apart from each other, wherein the head module is configured to bond a die onto the substrate, and a controller configured to control the head module. The head module is configured to move to a first position in a state in which the first bonding head and the second bonding head have respectively picked up a first die and a second die. At the first position, the first bonding head is configured to descend and bond the first die onto a first non-defective chip of the substrate, and the second bonding head is configured to descend and bond the second die onto a second non-defective chip of the substrate.

### CROSS-REFERENCE TO RELATED APPLICATION

This application claims priority from Korean Patent Application No. 10-2024-0110678 filed on Aug. 19, 2024 in the Korean Intellectual Property Office, and all the benefits accruing therefrom under 35 U.S.C. 119, the contents of which in its entirety are herein incorporated by reference.

### BACKGROUND

A wafer in which a plurality of semiconductor devices are formed is divided into a plurality of dies through a dicing process. Each of the individualized dies is bonded to a substrate such as a lead frame, a printed circuit board, or a wafer. In order to increase the productivity of a highly integrated semiconductor device such as HBM (High Bandwidth Memory), it is desired to minimize the number of movements and/or a distance of movement of a head module of a die bonding apparatus.

### SUMMARY

The present disclosure relates to semiconductor-device manufacturing equipment that minimizes the number of movements and/or a distance of movement of a head module.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims and combinations thereof.

In general, according to some aspects, semiconductor-device manufacturing equipment incudes a stage for supporting a substrate having a plurality of chips formed therein; a head module disposed on top of the stage and including a first bonding head and a second bonding head spaced apart from each other, wherein the head module is configured to bond a die onto the substrate; and a controller configured to control the head module, wherein the controller is configured to control the head module such that: the head module moves to a first position in a state in which the first bonding head and the second bonding head have respectively picked up a first die and a second die; at the first position, the first bonding head descends and bonds the first die onto a first non-defective chip of the substrate; and at the first position, the second bonding head descends and bonds the second die onto a second non-defective chip of the substrate.

In general, according to some aspects, semiconductor-device manufacturing equipment incudes a stage for supporting a substrate having a plurality of chips formed therein; a head module disposed on top of the stage and including a first bonding head and a second bonding head spaced apart from each other, wherein the head module is configured to bond a die onto the substrate; and a controller configured to control the head module, wherein the controller is configured to control the head module such that: in a state in which the first bonding head and the second bonding head have respectively picked up a first die and a second die, the head module to move in one direction and then moves along an arc path around the first bonding head so that the head module moves to a target position on the substrate; at the target position, the first bonding head descends and bonds the first die on a first non-defective chip of the substrate; and at the target position, the second bonding head descends and bonds the second die on a second non-defective chip of the substrate.

In general, according to some aspects, semiconductor-device manufacturing equipment incudes a stage for supporting a substrate having a plurality of chips formed therein; a head module disposed on top of the stage and including a first bonding head and a second bonding head spaced apart from each other, wherein the head module is configured to bond a die onto the substrate; and a controller configured to control the head module, wherein the controller is configured to control the head module such that: the head module to move to a first position along one direction; at the first position, the first bonding head descends to perform a first bonding operation on a first non-defective chip of the substrate; and at the first position, the second bonding head descends to perform a second bonding operation on a second non-defective chip of the substrate, wherein the first non-defective chip and the second non-defective chip are arranged along the one direction, wherein at least one chip is disposed between the first non-defective chip and the second non-defective chip, wherein a spacing between the first non-defective chip and the second non-defective chip is equal to a spacing between the first bonding head and the second bonding head.

The specific details of other implementations are included in the detailed description and drawings.

### BRIEF DESCRIPTION OF DRAWINGS

The above and other aspects and features of the present disclosure will become more apparent by describing in detail implementations thereof with reference to the attached drawings.

FIG. 1 is a block diagram for illustrating an example of semiconductor-device manufacturing.

FIG. 2 is a conceptual diagram for illustrating an example of a die pick-up apparatus of FIG. 1.

FIG. 3 and FIG. 4 are conceptual diagrams for illustrating an example of a die bonding apparatus of FIG. 1.

FIG. 5 is an example diagram for illustrating a substrate to which a plurality of dies are to be bonded.

FIG. 6 is an example enlarged diagram of an area 11 of FIG. 5.

FIG. 7 is a flowchart for illustrating an example of a bonding process of semiconductor-device manufacturing equipment.

FIGS. 8, 9, 10, and 11 are diagrams of intermediate structures corresponding to intermediate steps for illustrating an example of the bonding process as illustrated in FIG. 7.

FIGS. 12, 13, 14, and 15 are diagrams of intermediate structures corresponding to intermediate steps for illustrating an example of the bonding process illustrated in FIG. 7.

FIG. 16A is a flowchart for illustrating an example of a bonding process of semiconductor-device manufacturing equipment.

FIG. 16B is a flowchart for illustrating an example of a bonding process of semiconductor-device manufacturing equipment.

FIG. 17 is a diagram for illustrating an example of an arc motion of a head module.

FIG. 18 is a diagram for illustrating an example of the bonding process of FIG. 16A.

FIG. 19 is a diagram for illustrating an example of a result obtained by each of the bonding process of FIG. 7 and the bonding process of FIG. 16A/FIG. 16B.

FIG. 20 is a diagram for illustrating an example of a bonding process of semiconductor-device manufacturing equipment.

FIGS. 21, 22, 23, 24, 25, 26, and 27 are diagrams of intermediate structures corresponding to intermediate steps for illustrating an example of the bonding process illustrated in FIG. 20.

FIG. 28 is a diagram for illustrating an example of a bonding process of semiconductor-device manufacturing equipment.

FIG. 29 is a block diagram for illustrating an example of semiconductor-device manufacturing equipment.

FIG. 30 is a diagram for illustrating an example of a post-bonder illustrated in FIG. 29.

### DETAILED DESCRIPTIONS

Hereinafter, implementations of the present disclosure will be described in detail with reference to the attached drawings. The same reference numerals are used for the same components in the drawings, and duplicate descriptions thereof are omitted.

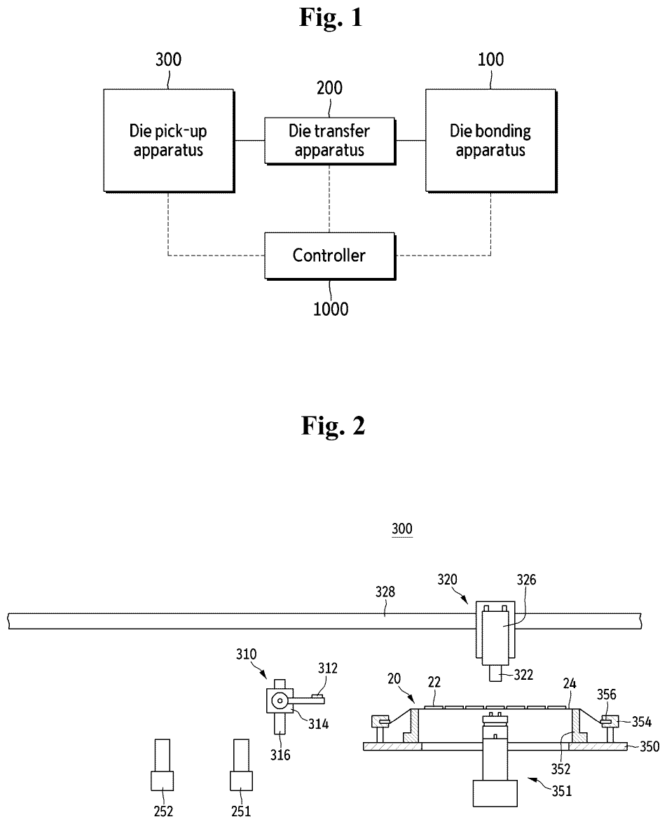

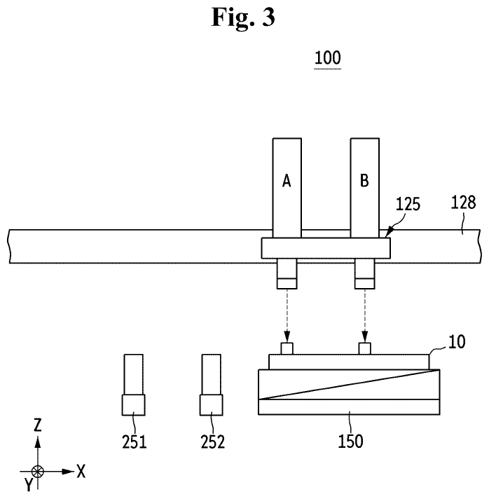

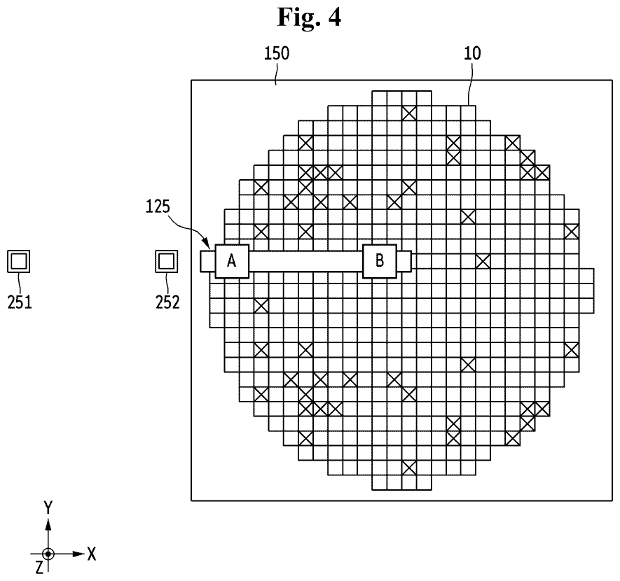

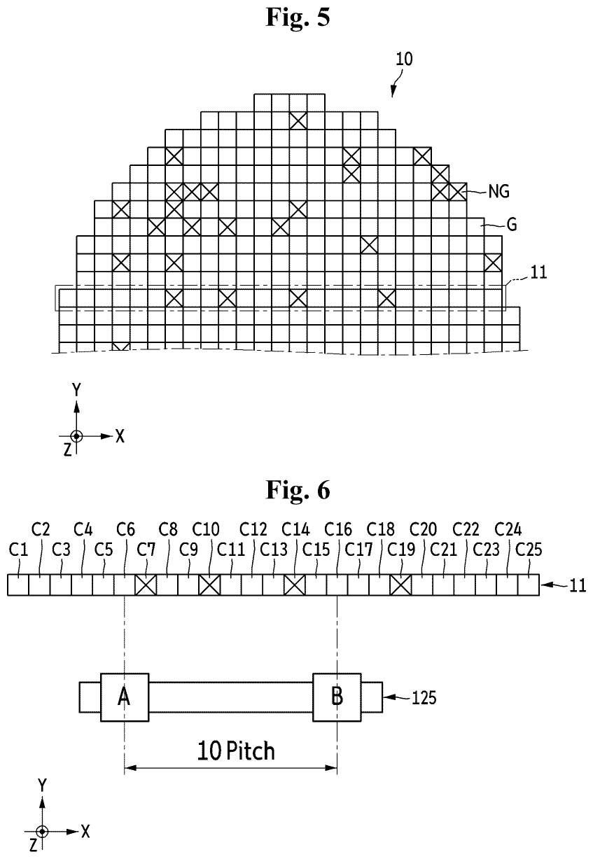

FIG. 1 is a block diagram for illustrating an example of semiconductor-device manufacturing equipment. FIG. 2 is a conceptual diagram for illustrating an example of a die pick-up apparatus of FIG. 1. FIG. 3 and FIG. 4 are conceptual diagrams for illustrating an example of a die bonding apparatus of FIG. 1. FIG. 5 is an example diagram for illustrating a substrate to which a plurality of dies are to be bonded. FIG. 6 is an example enlarged diagram of an area 11 of FIG. 5.

First, referring to FIG. 1, the semiconductor-device manufacturing equipment includes a die bonding apparatus 100, a die transfer apparatus 200, a die pick-up apparatus 300, and a controller 1000. The controller 1000 controls, manages, and monitors an operation of each of the die bonding apparatus 100, the die transfer apparatus 200, and the die pick-up apparatus 300, which will be described below.

The die pick-up apparatus 300 picks up a die from a wafer divided into a plurality of dies. An example configuration thereof is described below using FIG. 2.

The die transfer apparatus 200 may reciprocate between the die pick-up apparatus 300 and the die bonding apparatus 100. That is, the die transfer apparatus 200 receives a die from the die pick-up apparatus 300, and then moves from a vicinity of the die pick-up apparatus 300 to a vicinity of the die bonding apparatus 100.

The die bonding apparatus 100 picks up the die transported by the die transfer apparatus 200 and bonds the picked-up die onto the substrate. An example configuration thereof is described below using FIG. 3 and FIG. 4.

Referring to FIG. 2, an extension ring 352 and a clamp 354 are installed on a stage 350.

The wafer 20 is subjected to dicing to form a plurality of dies 22. The wafer 20 is attached to a dicing tape 24, and the extension ring 352 supports the dicing tape 24 while being disposed between the wafer 20 and a mount frame 356. While the clamp 354 grasps the mount frame 356, the clamp moves down. As the clamp 354 moves down, the dicing tape 24 is expanded, and accordingly, a spacing between adjacent ones of the plurality of dies 22 is increased.

A die ejector 351 is disposed under the stage 350 and configured to selectively remove the die 22 from the dicing tape 24. The die ejector 351 is equipped with an ejector member for pushing upwardly the die 22 to be picked up. The die 22 removed at least partly from the dicing tape 24 as the ejector member moves up is picked up by a die pick-up unit 320.

The die pick-up unit 320 is disposed on top of the wafer 20 and includes a picker 322 for picking up dies 22 one by one, a picker driver 326 and 328 for moving the picker 322 in a vertical/horizontal direction, and a flipper 310 for receiving the die 22 picked up by the picker 322 from the picker 322, turning the received die 22 upside down, and then placing the turned die on a die shuttle 251 and 252 (i.e., the die transfer apparatus 200).

The picker 322 may vacuum-absorb the die 22 using vacuum pressure.

The picker driver 326 and 328 may include a vertical driver 326 for moving the picker 322 in a vertical direction and a horizontal driver 328 for moving the picker 322 in a horizontal direction. In one example, each of the vertical driver 326 and the horizontal driver 328 may include a linear motor.

The flipper 310 may include a vacuum nozzle 312 for vacuum-absorbing the die 22, a rotation driver 314 for turning the vacuum nozzle 312 upside down, and a driver 316 for moving the vacuum nozzle 312 in the vertical/horizontal direction to place the die 22 turned upside down by the rotation driver 314 on the die shuttle 251 and 252.

Specifically, the die 22 picked up by the picker 322 may be transferred onto the vacuum nozzle 312. Then, the vacuum nozzle 312 may vacuum-absorb the die 22 using vacuum pressure, and then, the rotation driver 314 may turn upside down the die 22. After the die 22 has been turned upside down, the driver 316 may horizontally move and lower the vacuum nozzle 312 to put the die 22 on the die shuttle 251 and 252. At this time, the flipper 310 may be positioned so that the turned die 22 is positioned on top of the die shuttle 251 and 252.

Although an example in which the die 22 is turned upside down and then the turned die 22 is placed on the die shuttle 251 and 252 has been described above, implementations of the present disclosure are not limited thereto. When the turning upside down is not required according to a process recipe, the picker 322 may pick up the die 22 and put the die directly on the die shuttle 251 and 252 without turning the die upside down.

When the die shuttle 251 and 252 has received the die 22 from the flipper 310, the die shuttle moves from a vicinity of the die pick-up apparatus 300 to a vicinity of the die bonding apparatus 100.

Referring to FIG. 3 and FIG. 4, the die bonding apparatus 100 includes a stage 150 and a head module 125. A substrate 10 in which a plurality of chips have been formed is positioned on the stage 150.

The head module 125 may be disposed on top of the stage 150 and may be movable horizontally and/or vertically under an operation of a driver 128. For example, the head module 125 may be movable in a first direction X, a second direction Y, and a third direction Z. However, implementations of the present disclosure are not limited thereto. The head module 125 includes a plurality of bonding heads A and B that are spaced apart from each other. A spacing between the first bonding head A and the second bonding head B may be substantially equal to a spacing between the first die shuttle 251 and the second die shuttle 252. That is, the first bonding head A and the second bonding head B may descend simultaneously to simultaneously pick up the die from the first die shuttle 251 and the die from the second die shuttle 252, respectively.

As illustrated, a plurality of chips of the substrate 10 may be arranged along the first direction X and the second direction Y.

In this regard, referring to FIG. 5, a plurality of chips are formed in the substrate 10. The plurality of chips includes a non-defective chip G and a defective chip NG. The head module 125 may bond the die onto the non-defective chip G and may not bond the die onto the defective chip NG.

In this regard, referring to FIG. 6, 25 chips are arranged in a line along the first direction X. Among the 25 chips, chips C1, C2, C3, C4, C5, C6, C8, C9, C11, C12, C13, C15, C16, C17, C18, C20, C21, C22, C23, C24, and C25 are non-defective chips, while chips C7, C10, C14, and C19 are defective chips.

Alternatively, the first bonding head A and the second bonding head B are spaced apart from each other. The first bonding head A and the second bonding head B may be spaced apart from each other by a sum of the widths of several consecutively arranged chips. In some implementations, it is assumed that the first bonding head A and the second bonding head B are spaced from each other by a sum of the widths of 10 consecutively arranged chips. In the drawing, 1 pitch means a width of 1 chip, and therefore, 10 pitches means a sum of the widths of 10 chips.

The controller (refer to 1000 in FIG. 1) may control a movement position of the head module 125 using map data indicating whether each of the plurality of chips formed in the substrate 10 is a non-defective chip or a defective chip.

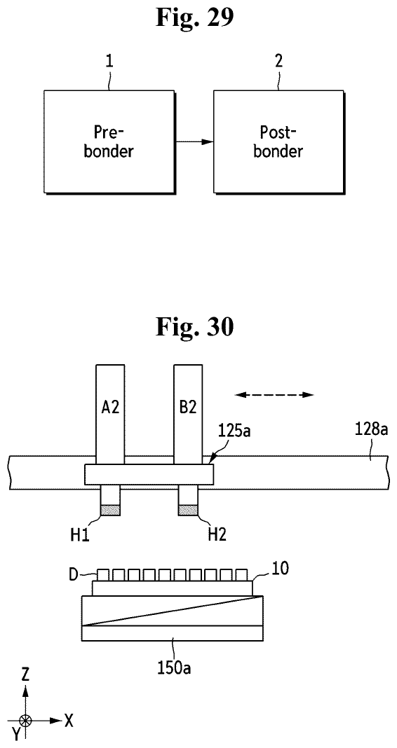

Furthermore, the controller 1000 controls the die bonding apparatus (refer to 100 in FIG. 1), a pre-bonder (refer to 1 in FIG. 29), or a post-bonder (refer to 2 in FIG. 29) to perform the bonding processes as described below. The controller 1000 includes a memory and a processor, etc. The memory includes instructions to perform operations as described below, and the processor operates according to the instructions.

Hereinafter, an operation of the head module 125 is described in detail.

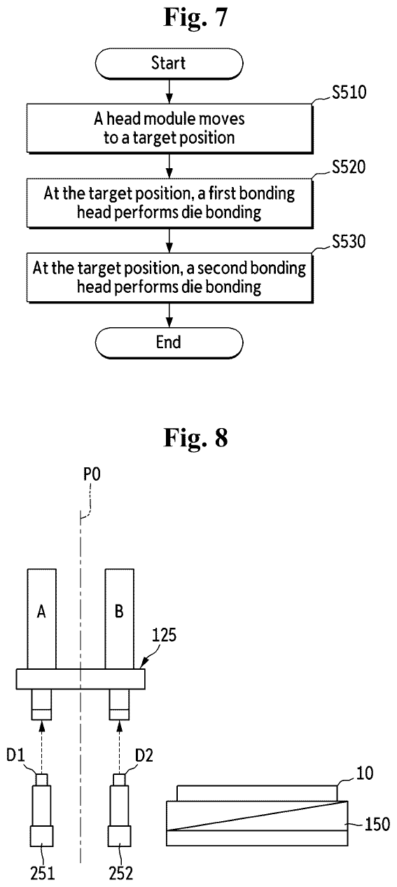

FIG. 7 is a flowchart for illustrating an example of a bonding process of semiconductor-device manufacturing equipment. FIGS. 8, 9, 10, and 11 are diagrams of intermediate structures corresponding to intermediate steps for illustrating an example of the bonding process illustrated in FIG. 7. FIGS. 8, 9, 10, and 11 illustrate an example in which a first die is bonded to a first non-defective chip (e.g., refer to C1 in FIG. 6) and a second die is bonded to a second non-defective chip (e.g., refer to C11 in FIG. 6).

Referring to FIG. 7, in a state in which the head module 125 has picked up the dies, the head module moves to a target position in S510.

Specifically, as shown in FIG. 8, the head module 125 is positioned on the die shuttle 251 and 252 (refer to a start position P0). A first die D1 is positioned on the first die shuttle 251, and a second die D2 is positioned on the second die shuttle 252. The first bonding head A and the second bonding head B pick up the first die D1 and the second die D2 from the first die shuttle 251 and the second die shuttle 252, respectively.

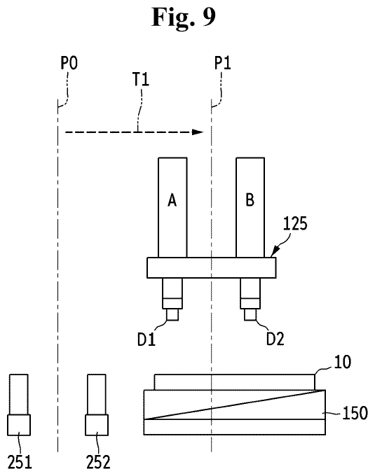

Then, as shown in FIG. 9, the head module 125 moves to the target position (e.g., a first position P1) on the substrate 10 (refer to a reference numeral T1). The head module 125 moves along a direction in which the plurality of chips are arranged in a line (e.g., the first direction X). That is, the head module 125 moves to the first position P1 in a state in which the first bonding head A and the second bonding head B have picked up the first die D1 and the second die D2, respectively.

Referring again to FIG. 7, at the target position, the first bonding head A performs die bonding in S520, and the second bonding head B performs die bonding in S530.

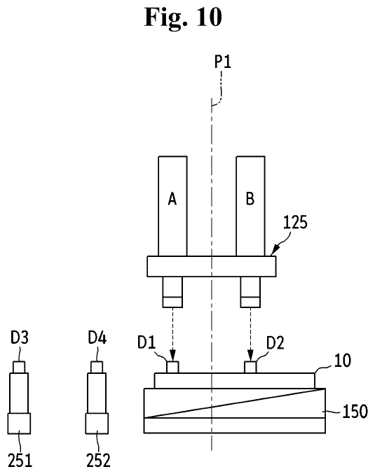

Specifically, referring to FIG. 10, in a state in which the head module 125 does not move from the target position (i.e., the first position P1), the first bonding head A bonds the first die D1 onto the first non-defective chip (e.g., C1) of the substrate 10, and the second bonding head B bonds the second die D2 onto the second non-defective chip (e.g., C11) of the substrate 10. The first non-defective chip C1 and the second non-defective chip C11 are spaced apart from each other. That is, one or more chips non-defective chips or defective chips are interposed between the first non-defective chip C1 and the second non-defective chip C11.

The first bonding head A and the second bonding head B may descend simultaneously to simultaneously bond the first die D1 and the second die D2 onto the first non-defective chip C1 and the second non-defective chip C11, respectively. Alternatively, the first bonding head A and the second bonding head B may descend sequentially to sequentially bond the first die D1 and the second die D2 onto the first non-defective chip C1 and the second non-defective chip C11, respectively. Even when the first bonding head A and the second bonding head B descend sequentially, the head module 125 does not move from the target position.

Therefore, the spacing between the first bonding head A and the second bonding head B is equal to the spacing between a bonding position of the first die D1 and a bonding position of the second die D2. That is, the spacing between the first bonding head A and the second bonding head B is equal to the spacing between the first non-defective chip (e.g., C1) and the second non-defective chip (e.g., C11).

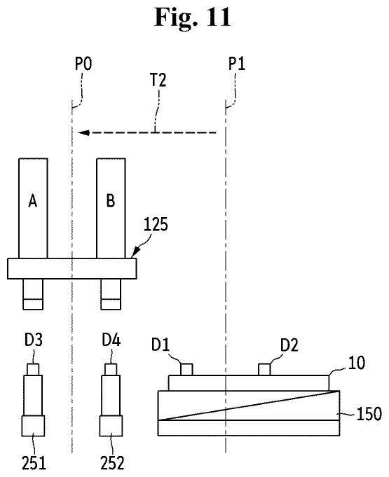

Next, referring to FIG. 11, the head module 125 moves from the first position P1 and returns to the starting position P0 (refer to a reference numeral T2).

According to some implementations of the present disclosure, the first bonding head A and the second bonding head B bond the first die D1 and the second die D2, respectively such that the first die D1 and the second die D2 are not directly adjacent to each other. That is, while the first bonding head A and the second bonding head B bond the first die D1 and the second die D2, respectively, the first bonding head A and the second bonding head B are spaced from each other by the sum of the widths of several consecutively arranged chips. In order that the first bonding head A and the second bonding head B bond the first die D1 and the second die D2, respectively such that the first die D1 and the second die D2 are directly adjacent to each other, the first bonding head A should bond the first die D1, and then, the head module 125 should move, and then the second bonding head B should bond the second die D2. However, according to some implementations of the present disclosure, the first bonding head A and the second bonding head B simultaneously bond the first die D1 and the second die D2 in a state in which the head module 125 does not move from the target position (e.g., the first position P1). That is, there is no movement of the head module 125 while the first bonding head A and the second bonding head B bond the first die D1 and the second die D2, respectively. Thus, an overall bonding time may be reduced.

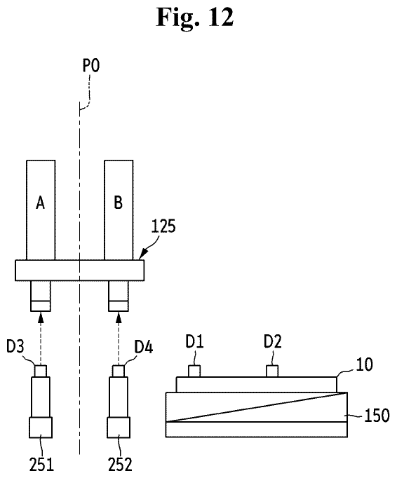

FIGS. 12, 13, 14, and 15 are diagrams of intermediate structures corresponding to intermediate steps for illustrating an example of the bonding process illustrated in FIG. 7. Referring to FIG. 12 to FIG. 15, the head module 125 bonds the first die D1 and the second die D2, and then bonds a third die D3 and a fourth die D4.

Referring to FIG. 12, the head module 125 is positioned on the die shuttle 251 and 252 (refer to the start position P0). The third die D3 is positioned on the first die shuttle 251, and the fourth die D4 is positioned on the second die shuttle 252. The first bonding head A and the second bonding head B pick up the third die D3 and the fourth die D4 from the first die shuttle 251 and the second die shuttle 252, respectively.

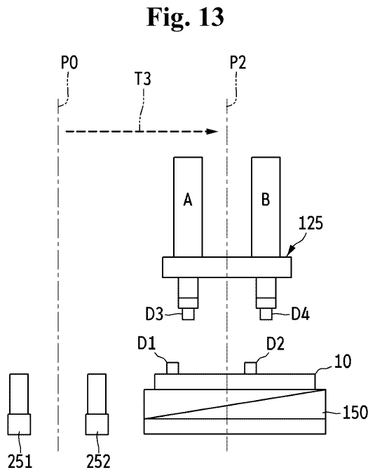

Next, as shown in FIG. 13, the head module 125 moves to a target position (e.g., a second position P2) on the substrate 10 (refer to a reference numeral T3). That is, the head module 125 moves to the second position P2 in a state in which the first bonding head A and the second bonding head B have picked up the third die D3 and the fourth die D4, respectively.

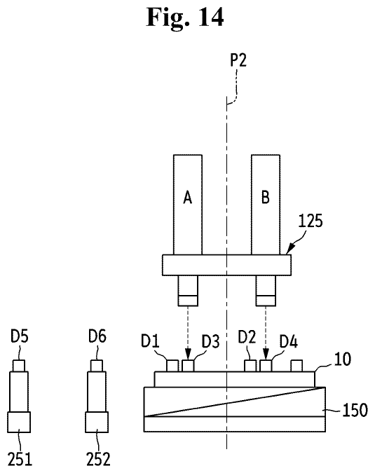

Next, as shown in FIG. 14, while the head module 125 does not move from the target position (i.e., the second position P2), the first bonding head A bonds the third die D3 on a third non-defective chip (e.g., refer to C2 in FIG. 6) of the substrate 10, and the second bonding head B bonds the fourth die D4 on a fourth non-defective chip (e.g., refer to C12 in FIG. 6) of the substrate 10. The first bonding head A and the second bonding head B may be lowered simultaneously to simultaneously bond the third die D3 and the fourth die D4. Alternatively, the first bonding head A and the second bonding head B may be lowered sequentially to sequentially bond the third die D3 and the fourth die D4.

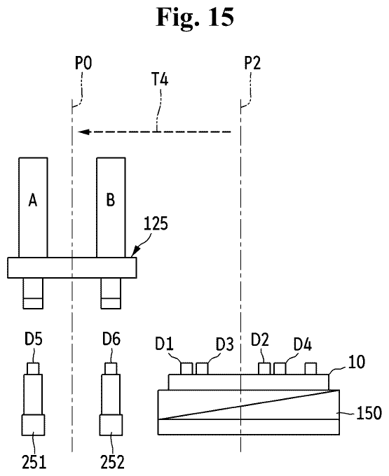

Next, referring to FIG. 15, the head module 125 moves from the second position P2 and returns to the starting position P0 (refer to a reference numeral T4).

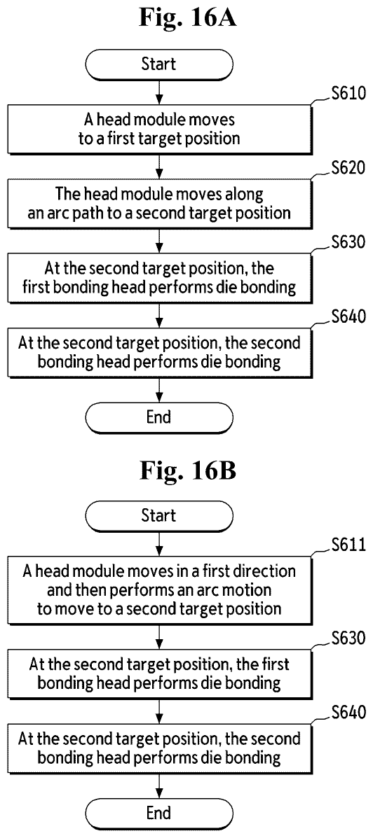

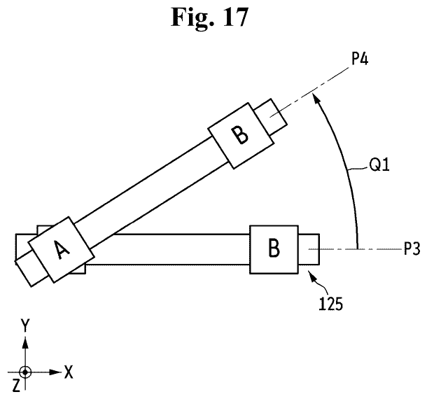

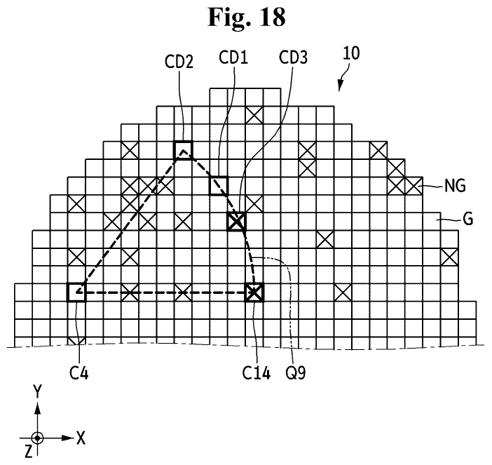

FIG. 16A is a flowchart for illustrating an example of a bonding process of semiconductor-device manufacturing equipment. FIG. 16B is a flowchart for illustrating an example of a bonding process of semiconductor-device manufacturing equipment. FIG. 17 is a diagram for illustrating an example of an arc motion of the head module. FIG. 18 is a diagram for illustrating an example of the bonding process of FIG. 16A.

Referring to FIG. 16A, FIG. 17, and FIG. 18, in a state in which the head module 125 has picked up the dies, the head module moves to a first target position (refer to S610 of FIG. 16A).

Specifically, the head module 125 moves along the first direction X and stops at the first target position. At the first target position, the first bonding head A is positioned directly on top of the non-defective chip C4, and the second bonding head B is positioned directly on top of the defective chip C14.

Subsequently, the head module 125 moves along an arc path to a second target position (refer to S620 in FIG. 16A).

Specifically, the head module 125 moves along an arc path around the first bonding head A (refer to Q1 in FIG. 17) so as to move from the first target position (refer to P3 in FIG. 17) to the second target position (refer to P4 in FIG. 17). A method for determining the second target position P4 is described as follows.

As illustrated in FIG. 18, referring to a fan-shaped arc Q9 indicated by a dotted line, when the head module 125 moves along an arc path around the first bonding head A, at least one candidate position CD1, CD2, and CD3 at which the second bonding head B may perform a bonding operation may be derived.

The controller checks whether the bonding operation is possible at the candidate positions CD1, CD2, and CD3. For example, the controller checks whether there is a non-defective chip at each of the candidate positions CD1, CD2, and CD3. Alternatively, the controller checks whether a die has been already bonded to a chip at each of the candidate positions CD1, CD2, and CD3, whether a chip at each of the candidate positions CD1, CD2, and CD3 is a defective chip, and a length of the arc along which the head module 125 moves along an arc path.

Specifically, a candidate position (e.g., CD3) with a defective chip or a candidate position at which a die has been already bonded to the chip is excluded from among at least one candidate position CD1, CD2, and CD3. Thereafter, the arc motion distance to each of the remaining candidate positions (e.g., CD1 and CD2) is calculated. The candidate position (e.g., CD1) with a shorter arc motion distance of the head module 125 may be selected. That is, the second target position P4 is determined so that the selected candidate position CD1 is positioned directly under the second bonding head B via the arc motion of the head module 125.

Next, at the second target position P4, the first bonding head A performs die bonding (refer to S630 in FIG. 16A), and the second bonding head B performs die bonding (refer to S640 in FIG. 16A).

In one example, the bonding process of FIG. 16B differs from the bonding process of FIG. 16A in that steps S610 and S620 in FIG. 16A are performed simultaneously. That is, the head module 125 moves in the first direction X and then performs an arc motion to move to the second target position (refer to S611 in FIG. 16B). At the second target position, the first bonding head A performs the die bonding in S620, and the second bonding head B performs the die bonding in S630.

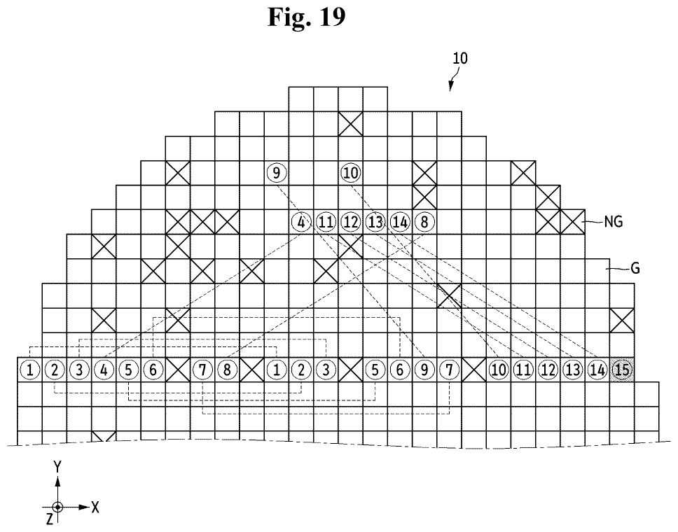

FIG. 19 is a diagram for illustrate an example of the result performed by each of the bonding process of FIG. 7 and the bonding process of FIG. 16A/FIG. 16B.

Referring to FIG. 19, a plurality of chips are formed in the substrate 10, and numbers \textcircled{1} to \textcircled{15} are allocated to the plurality of chips, respectively. Two chips indicated with the same number (for example, \textcircled{1}) and connected to each other via a dotted line may be simultaneously subjected to bonding operations by the first bonding head A and the second bonding head B of the head module 125, respectively.

For example, corresponding dies are respectively bonded onto chips indicated with numbers \textcircled{1}, \textcircled{2}, \textcircled{3}, \textcircled{5}, \textcircled{6}, and \textcircled{7} according to the bonding process of FIG. 7 (hereinafter, a first bonding process).

Corresponding dies are respectively bonded onto chips indicated with numbers \textcircled{4}, \textcircled{8}, \textcircled{9}, \textcircled{10}, \textcircled{11}, \textcircled{12}, \textcircled{13}, and \textcircled{14}, according to the bonding process of FIG. 16A/FIG. 16B (hereinafter, a second bonding process).

The chip indicated by the number \textcircled{15} is subjected to an independent bonding operation.

Referring to FIG. 6 and FIG. 19, the chips C1 and C11 are bonded to the dies to in the first bonding process such that the chip C1 is bonded to the die using the first bonding head A and the chip C11 is bonded to the die using the second bonding head B (refer to number \textcircled{1}).

Next, the chips C2 and C12 are bonded to the dies to in the first bonding process such that the chip C2 is bonded to the die using the first bonding head A and the chip C12 is bonded to the die using the second bonding head B (refer to number \textcircled{2})

Next, the chips C3 and C13 are bonded to the dies to in the first bonding process such that the chip C3 is bonded to the die using the first bonding head A and the chip C13 is bonded to the die using the second bonding head B (refer to number \textcircled{3}).

Next, since the chip C14 is a defective chip, the chips C4 and C14 are not simultaneously bonded to the dies in the first bonding process. Therefore, in the second bonding process, the chip C4 is bonded to the die while another non-defective chip is bonded to the die (refer to number \textcircled{4}).

Next, the chips C5 and C15 are bonded to the dies to in the first bonding process such that the chip C5 is bonded to the die using the first bonding head A and the chip C15 is bonded to the die using the second bonding head B (refer to number \textcircled{5}).

Next, the chips C6 and C16 are bonded to the dies to in the first bonding process such that the chip C6 is bonded to the die using the first bonding head A and the chip C16 is bonded to the die using the second bonding head B (refer to number \textcircled{6}).

Since the chip C7 is a defective chip, the die is not bonded to the chip C7.

Next, the chips C8 and C18 are bonded to the dies to in the first bonding process such that the chip C8 is bonded to the die using the first bonding head A and the chip C18 is bonded to the die using the second bonding head B (refer to number \textcircled{7}).

Next, since the chip C9 is a defective chip, the chips C9 and C19 are not simultaneously bonded to the dies in the first bonding process. Therefore, in the second bonding process, the chip C9 is bonded to the die while another non-defective chip is bonded to the die (refer to number \textcircled{8}).

Next, since the chip C10 is a defective chip, the die is not bonded to the chip C10.

Corresponding dies have been already respectively bonded onto the chips C11, C12, C13, C15, and C16 in previous bonding processes.

Next, the chip C17 is bonded to the die while another non-defective chip is bonded to the die according to the second bonding process (refer to number \textcircled{9})

A corresponding die has been already bonded onto the chip C18 in a previous bonding process.

Since the chip C19 is a defective chip, no die is bonded to the chip C19.

Next, the chip C20 is bonded to the die while another non-defective chip is bonded to the die according to the second bonding process (refer to number \textcircled{10}).

Next, the chip C21 is bonded to the die while another non-defective chip is bonded to the die according to the second bonding process (refer to number \textcircled{11}).

Next, the chip C22 is bonded to the die while another non-defective chip is bonded to the die according to the second bonding process (refer to number \textcircled{12}).

Next, the chip C23 is bonded to the die while another non-defective chip is bonded to the die according to the second bonding process (refer to number \textcircled{13}).

Next, the chip C24 is bonded to the die while another non-defective chip is bonded to the die according to the second bonding process (refer to number \textcircled{14}).

Next, there is no another non-defective chip together with which the bonding operation is to be performed on the chip C25 according to the second bonding process. Thus, the chip C25 may be bonded to the die alone.

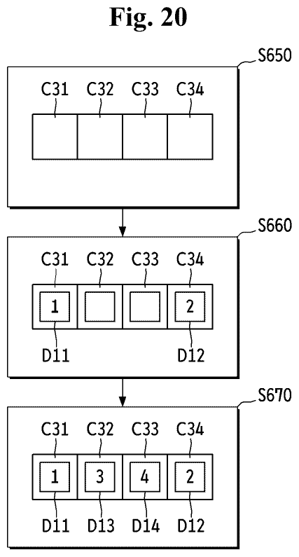

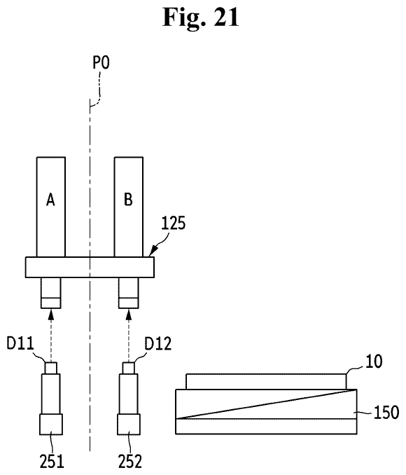

FIG. 20 is a diagram for illustrating an example of a bonding process of semiconductor-device manufacturing equipment. FIGS. 21, 22, 23, 24, 25, 26, and 27 are diagrams of intermediate structures corresponding to intermediate steps for illustrating an example of the bonding process illustrated in FIG. 20. Hereinafter, the bonding process as described using FIGS. 20 to 27 is referred to as a third bonding process.

Referring to FIG. 20, it is assumed that several chips arranged in one direction (for example, in the first direction X) in the substrate 10 cannot be bonded to the dies in the first bonding process and the second bonding process. FIG. 20 illustrates an example where a die is not bonded to each of four consecutively arranged chips C31, C32, C33, and C34 (refer to S650). A spacing between the two chips C31 and C34 disposed at the outermost side is smaller than a spacing between the first bonding head A and the second bonding head B.

According to the bonding process of FIG. 20, the two chips C31 and C34 disposed at the outermost side among several chips C31, C32, C33, and C34 are first respectively bonded to corresponding dies D11 and D12 in S660. Next, dies D13 and D14 are respectively bonded to corresponding two chips C32 and C33 disposed inwardly of the two chips C31 and C34 in S670.

Specifically, as shown in FIG. 21, the head module 125 is positioned on top of the die shuttle 251 and 252 (refer to the start position P0). The die D11 is positioned on top of the first die shuttle 251, and the die D12 is positioned on top of the second die shuttle 252. The first bonding head A and the second bonding head B pick up the die D11 and the die D12 from the first die shuttle 251 and the second die shuttle 252, respectively.

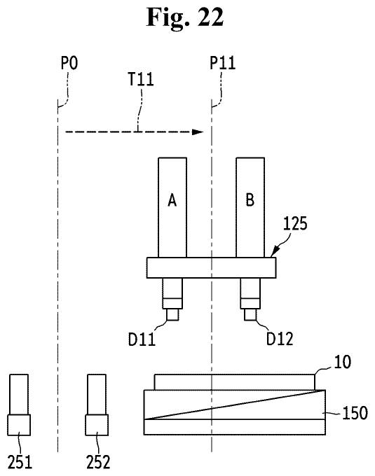

Then, as shown in FIG. 22, the head module 125 moves to a position P11 (refer to a reference numeral T11). That is, the head module 125 moves to the position P11 while the first bonding head A and the second bonding head B have picked up the die D11 and the die D12, respectively.

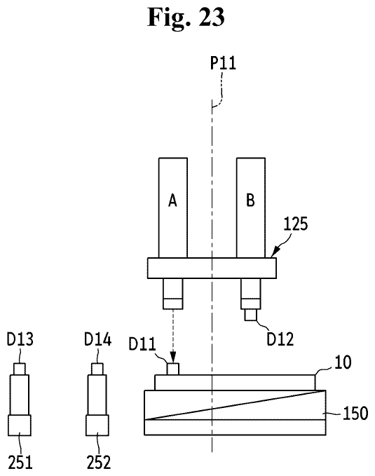

Next, as shown in FIG. 23, at the position P11, the first bonding head A places and bonds the die D11 onto the chip C31.

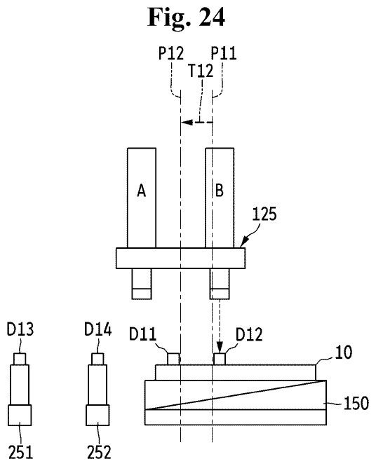

Next, as shown in FIG. 24, the head module 125 moves to a position P12 (refer to a reference numeral T12).

The second bonding head B places and bonds the die D12 onto the chip C34.

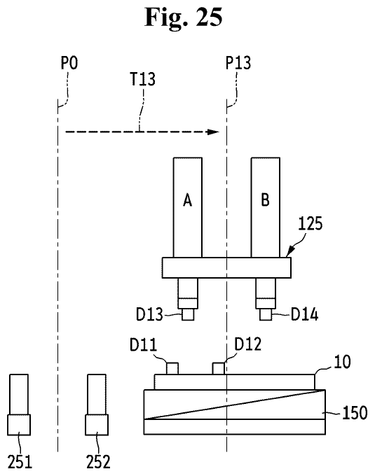

Next, as shown in FIG. 25, the head module 125 returns from the position P12 to the starting position P0, and the first bonding head A and the second bonding head B pick up the die D13 and the die D14, respectively. Next, in a state in which the first bonding head A and the second bonding head B have picked up the die D13 and the die D14, respectively, the head module 125 moves to a position P13 (refer to a reference numeral T13).

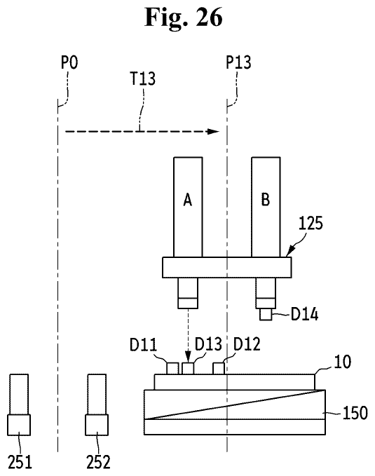

Next, as shown in FIG. 26, at the position P13, the first bonding head A places and bonds the die D13 onto the chip C32.

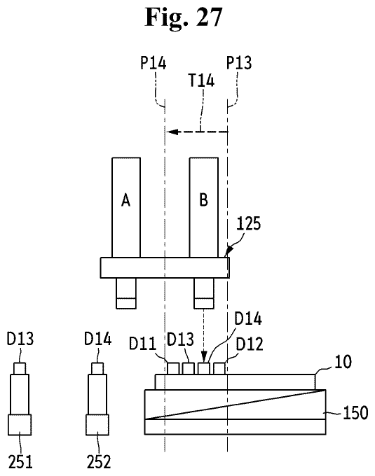

Next, as shown in FIG. 27, the head module 125 moves to a position P14 (refer to a reference numeral T14). The second bonding head B places and bonds the die D14 onto the chip C33.

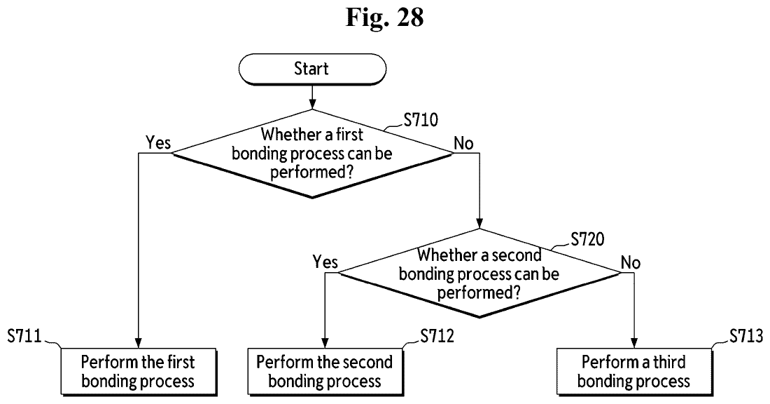

FIG. 28 is a diagram for illustrating an example of a bonding process of semiconductor-device manufacturing equipment.

Referring to FIG. 28, the controller (refer to 300 in FIG. 1) checks whether the first bonding process can be performed in S710.

When it is determined that the first bonding process can be performed (refer to Yes in S710), the first bonding process is performed. For example, it is assumed that the head module moves to a position on top of the substrate in the first direction (e.g., X direction), and that the spacing between the first bonding head and the second bonding head is W pitches where W is a natural number greater than or equal to 2. In this case, when there are two non-defective chips spaced from each other by the W pitches in the first direction, the first bonding head and the second bonding head may simultaneously bond the dies to the two non-defective chips, respectively.

Next, upon determination that the first bonding process cannot be performed (refer to No in S710), the controller checks whether the second bonding process can be performed in S720.

When it is determined that the second bonding process can be performed (refer to Yes in S720), the second bonding process is performed in S712. For example, when a non-defective chip is positioned directly under the first bonding head, while a defective chip is positioned directly under the second bonding head, the first bonding process cannot be performed. In this case, the head module is moved in the arc direction around the first bonding head to change the position of the head module, and then, it is checked whether there is a non-defective chip directly under the second bonding head. In order that the non-defective chip may be located directly under the second bonding head, the position of the head module may be changed, so that the first bonding head and the second bonding head may simultaneously bond the dies to the two non-defective chips, respectively.

Next, upon determination that the second bonding process cannot be performed (refer to No in S720), a third bonding process is performed in S713. For example, according to the third bonding process, instead of two bonding heads simultaneously bonding the dies, the two bonding heads sequentially and individually bond the dies. Alternatively, under assuming that there are several consecutively-arranged chips to which the first/second bonding process cannot be applied, first, the dies may be bonded to corresponding two chips disposed at the outermost side, respectively, and then the dies may be bonded to corresponding two chips disposed inwardly of the two chips disposed at the outermost side, respectively.

FIG. 29 is a block diagram for illustrating an example of semiconductor-device manufacturing equipment. FIG. 30 is a diagram for illustrating an example of a post-bonder illustrated in FIG. 29.

First, referring to FIG. 29, a process of bonding the die onto the substrate may include a pre-bonding process and a post-bonding process. The pre-bonding process is a process of positioning a die on a non-defective chip of a substrate at high precision and bonding the non-defective chip and the die to each other in a relatively weak manner.

The post-bonding process is a process for strongly bonding the pre-bonded non-defective chip and die to each other. For example, a scheme of applying heat and pressure to the pre-bonded non-defective chip and die to each other may be used in the post-bonding process.

A pre-bonder 1 is equipment that performs the pre-bonding process, and a post-bonder 2 is equipment that performs the post-bonding process.

The pre-bonder 1 may be the equipment as described using FIG. 2 to FIG. 4. However, implementations of the present disclosure are not limited thereto. The post-bonder 2 is described using FIG. 30.

Referring to FIG. 30, the post-bonder 2 positions the substrate 10 on a stage 150a. A plurality of chips have been formed in the substrate 10, and a die D has been pre-bonded onto a non-defective chip among the plurality of chips.

A head module 125a is placed on top of the stage 150a. The head module 125a may move horizontally and/or vertically under an operation of a driver 128a. The head module 125a may be movable in the first direction X, the second direction Y, and the third direction Z. However, implementations of the present disclosure are not limited thereto. The head module 125a includes two bonding heads A2 and B2. The two bonding heads A2 and B2 are spaced apart from each other. For example, the two bonding heads A2 and B2 may be spaced apart from each other by a sum of widths of several consecutively-arranged chips.

The spacing between the two bonding heads A2 and B2 may be the same as the spacing between the two die shuttles (refer to 251 and 252 in FIG. 3. However, implementations of the present disclosure are not limited thereto.

Furthermore, the spacing between the two bonding heads A2 and B2 may be equal to the spacing between the two bonding heads (refer to A and B in FIG. 3) of the pre-bonder 1. However, implementations of the present disclosure are not limited thereto.

Heaters H1 and H2 are installed in the two bonding heads A2 and B2, respectively. Using the heaters H1 and H2, the bonding heads A2 and B2 may apply heat to the pre-bonded non-defective chips and dies D to each other, respectively.

The head module 125a may perform the first bonding process, the second bonding process, and the third bonding process as described above.

That is, it is assumed that the head module 125a moves to a position on top of the substrate 10 in the first direction (for example, X direction), and that the spacing between the first bonding head A2 and the second bonding head B2 is W pitches (W is a natural number greater than or equal to 2). In this case, when there are two non-defective chips that are pre-bonded to each other and are spaced from each other by the W pitches in the first direction, the first bonding head A2 and the second bonding head B2 may simultaneously heat the two non-defective chips in the pre-bonded state, respectively to perform the post-bonding thereof.

Alternatively, the head module 125a is moved in the arc direction around the first bonding head A2 to change the position of the head module 125a, and then, it is checked whether there is a pre-bonded non-defective chip directly under the second bonding head B2. In order that there may be a pre-bonded non-defective chip directly under the second bonding head B2, the position of the head module 125a may be changed, so that the first bonding head A2 and the second bonding head B2 may simultaneously apply the heat to the two pre-bonded non-defective chips, respectively to perform the post-bonding thereof.

Alternatively, instead of the two bonding heads A and B bonding the dies simultaneously, the two bonding heads A and B may individually and sequentially bond the dies. Alternatively, under assuming that there are several consecutively-arranged chips to which the above-described bonding processes cannot be applied, the dies may be post-bonded to corresponding two chips disposed at the outermost side, respectively, and then the dies may be post-bonded to corresponding two chips disposed inwardly of the two chips disposed at the outermost side, respectively.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present disclosure have been described with reference to the accompanying drawings, the present disclosure is not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above is not restrictive but illustrative in all respects.

What is claimed is:

1. Semiconductor-device manufacturing equipment comprising:
a stage configured to support a substrate;
a head module disposed on top of the stage, the head module including a first bonding head and a second bonding head spaced apart from each other, wherein the head module is configured to bond a plurality of dies onto the substrate; and
a controller configured to cause the head module to move to a first position,
wherein at the first position, the first bonding head is configured to descend and bond a first die onto a first non-defective chip of the substrate, and
wherein at the first position, the second bonding head is configured to descend and bond a second die onto a second non-defective chip of the substrate.

2. The semiconductor-device manufacturing equipment of claim 1, wherein the plurality of chips are arranged in a line in a first direction,
wherein the head module is configured to move along the first direction to the first position,
wherein the first non-defective chip and the second non-defective chip are arranged along the first direction.

3. The semiconductor-device manufacturing equipment of claim 1, wherein the first non-defective chip and the second non-defective chip are spaced apart from each other, and
wherein a spacing between the first non-defective chip and the second non-defective chip is equal to a spacing between the first bonding head and the second bonding head.

4. The semiconductor-device manufacturing equipment of claim 1, comprising a die shuttle configured to supply the plurality of dies to the head module,
wherein the die shuttle includes a first shuttle and a second shuttle spaced apart from each other, and
wherein a spacing between the first shuttle and the second shuttle is equal to a spacing between the first bonding head and the second bonding head.

5. The semiconductor-device manufacturing equipment of claim 1, wherein the controller is configured to cause the head module to move to a second position,
wherein the head module is configured to move along an arc path around the first bonding head to move to a third position,
wherein, at the third position, the first bonding head is configured to descend and bond a third die onto a third non-defective chip of the substrate, and
wherein, at the third position, the second bonding head is configured to descend and bond a fourth die onto a fourth non-defective chip of the substrate.

6. The semiconductor-device manufacturing equipment of claim 1, wherein the controller is configured to cause the head module to move in a first direction and then move along an arc path around the first bonding head to a third position,
wherein, at the third position, the first bonding head is configured to descend and bond a third die onto a third non-defective chip of the substrate, and
wherein, at the third position, the second bonding head is configured to descend and bond a fourth die onto a fourth non-defective chip of the substrate.

7. The semiconductor-device manufacturing equipment of claim 6, wherein the controller is configured to:
predict a first candidate position and a second candidate position to which the head module can move along the arc path around the first bonding head;
check whether there is a defective chip directly under the second bonding head at the first candidate position or the second candidate position, or whether a die has been already bonded to a chip at the first candidate position or the second candidate position; and
calculate an arc movement distance to the first candidate position or the second candidate position.

8. The semiconductor-device manufacturing equipment of claim 1,
wherein the controller is configured to cause the head module to move to a fourth position,
wherein, at the fourth position, the first bonding head is configured to bond a fifth die onto a fifth non-defective chip,
wherein the head module is configured to move to a fifth position subsequent to moving to the fourth position, and
wherein, at the fifth position, the second bonding head is configured to bond a sixth die onto an eighth non-defective chip.

9. The semiconductor-device manufacturing equipment of claim 8, wherein the head module is configured to move to a sixth position subsequent to moving to the fifth position,
wherein, at the sixth position, the first bonding head is configured to bond a seventh die onto a sixth non-defective chip,
wherein the head module is configured to move to a seventh position subsequent to moving to the sixth position, and
wherein, at the seventh position, the second bonding head is configured to bond an eighth die onto a seventh non-defective chip.

10. The semiconductor-device manufacturing equipment of claim 1, wherein the controller is configured to determine a position to which the head module moves based on map data, the map data indicating whether each chip of a plurality of chips is a non-defective chip or a defective chip.

11. Semiconductor-device manufacturing equipment comprising:
a stage configured to support a substrate;
a head module disposed on top of the stage, the head module including a first bonding head and a second bonding head spaced apart from each other, wherein the head module is configured to bond a plurality of dies onto the substrate; and
a controller configured to place the head module in a first state,
wherein in the first state, the head module is configured to move in a first direction and to move along an arc path around the first bonding head to a target position on the substrate,
wherein, at the target position, the first bonding head is configured to descend and bond a first die on a first non-defective chip of the substrate, and
wherein, at the target position, the second bonding head is configured to descend and bond a second die on a second non-defective chip of the substrate.

12. The semiconductor-device manufacturing equipment of claim 11, wherein the controller is configured to:
predict a first candidate position and a second candidate position to which the head module can move along the arc path around the first bonding head; and
check whether a non-defective chip is positioned directly under the second bonding head at the first candidate position or the second candidate position.

13. The semiconductor-device manufacturing equipment of claim 12, wherein the controller is configured to:
check whether a defective chip is positioned directly under the second bonding head at the first candidate position or the second candidate position, or whether a die has been already bonded to a chip at the first candidate position or the second candidate position; and
calculate an arc motion distance to the first candidate position or the second candidate position.

14. The semiconductor-device manufacturing equipment of claim 11, comprising a die shuttle configured to supply the plurality of dies to the head module,
wherein the die shuttle includes a first shuttle and a second shuttle spaced apart from each other, and
wherein a spacing between the first shuttle and the second shuttle is equal to a spacing between the first bonding head and the second bonding head.

15. Semiconductor-device manufacturing equipment comprising:
a stage configured to support a substrate;
a head module disposed on top of the stage, the head module including a first bonding head and a second bonding head spaced apart from each other, wherein the head module is configured to bond a plurality of dies onto the substrate; and
a controller configured to cause the head module to move to a first position along a first direction,
wherein, at the first position, the first bonding head is configured to descend to perform a first bonding operation on a first chip,
wherein, at the first position, the second bonding head is configured to descend to perform a second bonding operation on a second chip positioned along the first direction with the first chip,
wherein a spacing between the first bonding head and the second bonding head is wide enough to cover a width of at least one chip.

16. The semiconductor-device manufacturing equipment of claim 15, wherein in the first bonding operation, the first bonding head is configured to descend to pre-bond a first die onto the first chip, and
wherein in the second bonding operation, the second bonding head is configured to descend to pre-bond a second die onto the second chip.

17. The semiconductor-device manufacturing equipment of claim 16,
wherein, in the first bonding operation, the first bonding head is configured to apply heat to the first chip and the first die pre-bonded to each other to completely bond the first chip and the first die to each other, and
wherein, in the second bonding operation, the second bonding head is configured to apply heat to the second chip and the second die pre-bonded to each other to completely bond the second chip and the second die to each other.

18. The semiconductor-device manufacturing equipment of claim 15, wherein
the head module is configured to move along the first direction and then move along an arc path around the first bonding head to reach to a second position,
wherein, at the second position, the first bonding head is configured to descend and perform a bonding operation on a third chip of the substrate, and
wherein, at the second position, the second bonding head is configured to descend and perform a bonding operation on a fourth chip of the substrate.

19. The semiconductor-device manufacturing equipment of claim 15,
wherein the head module is configured to move to a third position,
wherein, at the third position, the first bonding head is configured to perform a bonding operation on a fifth chip,
wherein the head module is configured to move to a fourth position subsequent to moving to the third position, and
wherein, at the fourth position, the second bonding head is configured to perform a bonding operation on an eighth chip, wherein a spacing between the fifth chip and the eighth chip is smaller than a spacing between the first bonding head and the second bonding head.

20. The semiconductor-device manufacturing equipment of claim 19, wherein
the head module is configured to move to a fifth position,
wherein, at the fifth position, the first bonding head is configured to perform a bonding operation on a sixth chip,
wherein the head module is configured to move to a sixth position subsequent to moving to the fifth position, and
wherein, at the sixth position, the second bonding head is configured to perform a bonding operation on a seventh chip.
